(19) United States
(12) Patent Application Publication
(10) Pub. No.: US 2006/0250147 A1
(43) Pub. Date: Nov. 9, 2006

(54) Insulating film measuring device, insulating film measuring method, insulating film evaluating device, insulating film evaluating method, substrate for electric discharge display element, and plasma display panel

(76) Inventors: Yukihiro Morita, Hirakata-shi (JP); Mikihiko Nishitani, Nara-shi (JP); Masatoshi Kitagawa, Osaka (JP); Takaharu Nagotomi, Osaka (JP)

Correspondence Address: SNELL & WILMER L.L.P., 600 ANTON BOULEVARD, SUITE 1400, COSTA MESA, CA, 92626, US

(21) Appl. No.: 10/568,985

(22) PCT Filed: Aug. 23, 2004
(86) PCT No.: PCT/JP04/12415

§ 371 Date: Feb. 21, 2006

(30) Foreign Application Priority Data
Aug. 26, 2003 (JP) 2003-301555

(51) Int. Cl. G01R 31/305

(52) U.S. Cl. 324/751

(57) ABSTRACT

A measuring device, a measuring method, and an evaluating device for easily and accurately obtaining information suitable to evaluate, for example, the discharge characteristic of an insulating film such as an MgO protective layer of a plasma display are provided. An MgO film surface, a sample to be measured, is irradiated with electrons or ions emitted from an electron gun (130) or an ion gun (140). The energy distribution of the secondary electrons emitted from the sample is measured by an electron spectrograph (150), and the spectrum data on the measured secondary electrons is supplied to an analyzing device (200). The analyzing device (200) analyzes the spectrum data and determines information (evaluation values) to evaluate the properties of the sample to be measured.

### TECHNICAL FIELD

The present invention relates to an insulating film evaluating device, and to an insulating film evaluating method and insulating film evaluating device, and in particular, to aspects of the measurement and evaluation of performance of a protective layer in a gas discharge panel.

### BACKGROUND ART

In recent years, in the light of rising expectations for high definition large screen televisions for applications such as Hi-Vision, the development of suitable displays, especially panel type displays such as Plasma Display Panels (referred to below as “PDPs”), has continued.

AC-type PDPs generally include: a front panel and a back panel provided in parallel; display electrodes and a dielectric glass layer disposed on the front panel; data electrodes, barrier ribs, and phosphor layers disposed on the back panel; and discharge gas enclosed in the gap between the two panels. Further, a protective layer is formed on the surface of the dielectric glass on the front the panel. This layer is required to have favorable sputter resistance and secondary electron emission characteristics, and is generally formed using an MgO film.

The lifetime and discharge performance of AC-type PDPs are strongly affected by the state of the film of protective layer and its deterioration. In particular, during a writing period of an operating PDP, a period beginning when a write pulse is applied between a data electrode and a display electrode and ending when discharge takes place in the written cell (a discharge lag time) is thought to be affected not only by the panel construction and the discharge gas, but also by properties relating to electrical charging and electron emission in the protective layer. Further, the reduction of a firing voltage Vf is an effective way to reduce the electricity consumption of a PDP, and this firing voltage Vf is strongly influenced by the electron emission properties of the protective layer. Thus, a capability to reliably manufacture protective layers with favorable properties is desired.

Hence, a technique is wanted for simply and accurately evaluating the discharge properties, and the like, of insulating films. There are several reasons for this. Firstly, if the properties of the protective layer can be accurately evaluated, it is possible, by using the results of the evaluation as feedback, to adjust process conditions in order to precisely manage certain areas of the manufacturing process for forming the protective layer. Secondly, although variation in the properties of the protective layers is inevitable in PDP manufacture, if the suitability of the properties can be evaluated at an early stage in the process, only those panels with favorable protective layers need be used in the next stage, and the yield of the process can be improved.

There are several methods for evaluating the properties of a protective layer. One well-known method is to base the evaluation on a coefficient of secondary electron emission for the surface of the protective layer (γ coefficient), which is found by measuring an amount of charge emitted from the surface of the protective layer as it is irradiated with ions.

Another proposed method is to evaluate the properties of the protective layer by making discharge occur in a protective layer formed on a substrate, and analyzing the form of the generated current wave, as described in Japanese laid open patent application number H11-86731.

However, though it is possible to evaluate the properties of a protective layer by measuring the γ coefficient of the protective layer as described above, the γ coefficient is not necessarily appropriate for accurately evaluating the discharge characteristics in a PDP. For example, though, for an MgO protective layer it is often stated that a higher secondary electron γ coefficient gives a lower firing voltage Vf, there have been reports that that correlation between the γ coefficient and the firing voltage Vf is low. This is thought to be because the y coefficient does not take the effects of electrical charging and the like into account, in spite of the MgO film being an insulator.

Further, although the method of Japanese laid-open patent application H11-86731 is considered to be effective, a technology for evaluating the protective layer from a different standpoint is wanted. Also, in order to perform evaluation using this method, a device is required for analyzing the current wave form.

It is for such reasons as these that a technology is wanted in the field of PDP manufacture for simply and accurately evaluating properties such as the discharge performance of insulating films. In particular, a technology is wanted for simply and accurately evaluating the discharge characteristics and charging properties of an MgO protective layer.

### DISCLOSURE OF THE INVENTION

The present invention was conceived to solve the stated problems and has an object of providing a measuring device, a measuring method, and an evaluating device capable of simply and accurately obtaining information suitable for evaluating, for instance, the discharge characteristics of an insulating film such as an MgO protective layer. A further object is to use this evaluation to contribute to an improved yield and the like in the manufacture of display devices.

Thus, in the present invention, when the properties of insulating films are evaluated, the insulating film to be measured is irradiated with ions, and the spectrum of secondary electrons emitted from the insulating film either during or after the irradiation is measured.

Alternatively, when the properties of insulating films are evaluated, the insulating film to be measured is irradiated the with a variable electron beam current, and a spectrum of secondary electrons emitted from the insulating film during electron irradiation is measured.

Note that here the term “insulating film” includes “semiconductor films”.

As described above, if the spectrum of secondary electrons emitted from the insulating film either during or after irradiation is measured, it is possible to accurately evaluate the properties of the insulating film by analyzing the obtained spectrum.

Specifically, in the present invention, the secondary electron spectrum measured in this way reflects a density of states for the electrons in the valence band of the insulating film. The density of states relates to characteristics bearing on electron emission from the valence band of the insulating film and the charging of the insulating film. Hence, by analyzing the spectrum, it is possible to measure the electron density of states in the valence bands of the insulating film, and discover characteristics relating to the charging thereof, and electron emission therefrom, the valence bands of the insulating film. Thus, since it is possible via the present invention, to discover the stated characteristics of the insulating film, the insulating film can be evaluated in a way that takes these characteristics into consideration.

The practical effect of the present invention is to make it possible, by accurately evaluating the performance of the insulating film in this way, to manage the manufacturing process precisely. This is achieved by using results of the evaluation as feedback to adjust the manufacturing conditions in the process for forming the insulating film. Further, the present invention enables the yield in the manufacture of components containing an insulating film to be improved, by evaluating whether or not a formed insulating film has properties suitable to the component, and only allowing the component to pass to the next stage in the process if the result of the evaluation is favorable.

When the spectrum is being measured, it is preferable that negative bias is applied to the insulating film.

The charge properties and electron properties of an insulating film can be evaluated by analyzing spectra measured in the way described above, and various forms of measurement and analysis of the spectra are conceivable, including those listed below below.

Detect, based on a secondary electron spectrum measurement result measured over time, at least one of an amount of variation of a rise position of a peak due to kinetic emission of secondary electrons and a rate of variation of the rise position.

Note here that the term “Peak due to kinetic emission” is not used to mean that the peak is generated solely by kinetic emission of secondary electrons. Instead, the term is used providing that a portion of the peak is generated due to kinetic emission of secondary electrons. Specifically, the “peak due to kinetic emission” described here is the peak which appears near energy levels corresponding to the negative bias applied at the time of measurement, and is not generated solely by kinetically emitted secondary electrons, but includes a contribution from potentially emitted secondary electrons. Further, when the incident energy is low, the proportion of electrons resulting from potential emission is high.

Detect, based on a secondary electron spectrum measurement result measured in over time, variation in a peak appearing at a lower energy level than the peak due to kinetic emission of secondary electrons.

“A peak which appears at a lower energy level than the peak due to kinetic emission of secondary electrons” appears at an energy level which is lower than the energy level (vacuum level Evac) that corresponds to the applied negative voltage, and could therefore also be termed as “a peak which appears at a energy level lower than a level corresponding to the applied negative voltage” or “a peak which appears at a lower energy level than the vacuum level”.

Find, based on a secondary electron spectrum measured over time after irradiation has stopped, an intensity of a peak appearing at a lower energy level than a peak due to kinetic emission of secondary electrons.

Find variation in the peak appearing at a lower energy level than the peak due to kinetic emission of secondary electrons.

Measure a spectrum of electrons emitted from the insulating film during ion irradiation and after the ion irradiation has stopped, and measure, based on the spectrum measured by the spectrum measurement unit, an energy difference between a first peak due to kinetic emission of secondary electrons measured during ion irradiation and a second peak appearing at a lower energy level after ion irradiation has stopped.

Irradiate the insulating film with a electron beam of variable intensity, measure a spectrum of secondary electrons emitted from the insulating film during electron irradiation, and find, as the intensity of the electron beam, varies a variation in a rise position of a peak that appears in a secondary electron spectrum measured by the spectrum measurement unit.

Here, in order to evaluate, using the methods above, an insulating film on a discharge display component substrate having a display area which includes display electrodes for applying a voltage during discharge display and the display-use insulating film covering the display-use electrodes, a test area for measuring the properties of the insulating layer, and in the test area, a test-use insulating film identical in type to the display-use insulating film may be provided.

It is possible to construct a PDP by providing a second substrate disposed an interval away from the discharge display component substrate, so as to be opposite the display-use insulating film, and filling the gap between the two substrates with a discharge gas.

It is preferable that the test-use insulating film is provided to be sufficiently spacious to accommodate irradiation from a whole ion beam from an ion beam irradiation device.

Further, it is preferable that the test area is provided outside the display area.

In this test area, it is preferable that a test-use electrode for applying a voltage from an external source is sandwiched between the test-use insulating film and the substrate.

It is preferable that the display-use film and the test-use film are formed simultaneously, and that the display electrodes and the test-use electrode are formed from a same type of material.

Further it is preferable that an electrode pad to which the voltage is applied and the test use electrode are connected.

### BRIEF DESCRIPTION OF THE DRAWINGS

FIG. 1 is a schematic diagram showing a structure of an insulating film evaluating device of an embodiment of the present invention;

FIG. 2 is a characteristic plot showing results from measurement over time of spectra of secondary electrons kinetically emitted from a sample;

FIG. 3A-3C show examples of spectra for secondary electrons emitted from a sample during or after ion irradiation;

FIGS. 4A and 4B show an example of a combined spectrum obtained by integrating the secondary electron spectra from the measured sample, and show, for MgO, a valence band density of states obtained from a band calculation;

FIG. 5 shows examples of secondary electron spectra observed as the sample was irradiated with an electron beam;

FIG. 6 is a characteristic plot showing the rise positions for the various peaks shown in FIG. 5, plotted against the intensity of the electron beam.

FIG. 7 is a perspective view showing the structure of an AC surface discharge type PDP of an embodiment of the present invention.

FIG. 8 is a plan view of a front panel used in the PDP; and

FIG. 9A-B is a cross-sectional view of part of the front panel.

### BEST MODE FOR CARRYING OUT THE INVENTION

A sample from which measurements are taken is a conducting substrate with an insulating film that is the subject of evaluation formed thereon. The sample is irradiated with ions from an inert gas, or electrons, while a negative voltage is applied to the substrate and a spectrum (the quantity of secondary electrons from each energy level) of secondary electrons generated from the sample is measured. The properties of the insulating film are evaluated by analyzing the obtained secondary electron spectrum.

Following is a detailed explanation of the measuring device and the measuring method used to perform this evaluation.

### First Embodiment

In the First Embodiment an MgO film formed on an Si substrate is used as a sample.

(Insulating Film Evaluating Device)

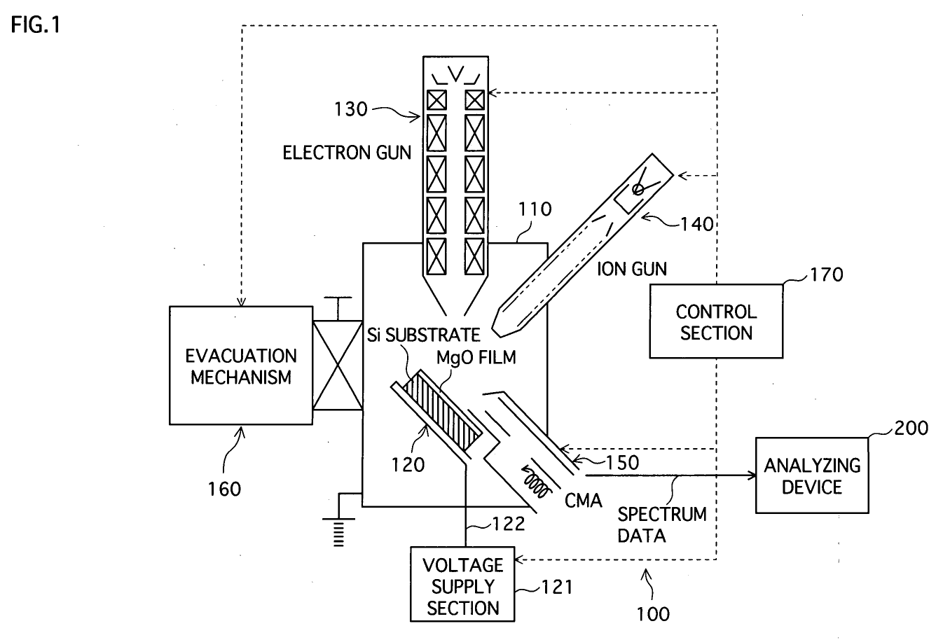

FIG. 1 is a schematic diagram showing a structure of an insulating film evaluating device of an embodiment of the present embodiment.

This evaluating device is constructed from a spectra measuring device 100 for measuring secondary electron spectra from the sample and an analyzing device 200 that, upon analysis of the measured secondary electron spectra, finds information (evaluation values) for evaluating the properties of the sample.

The spectra measuring device 100 is constructed from: a vacuum vessel 110; a sample stand 120 for mounting the sample (front panel); a voltage applying section 121 for applying a negative voltage to the sample; an electron gun 130 for irradiating the sample with electrons; an ion gun 140 for generating inert gas ions and irradiating the sample; a electron spectrograph (CMA) 150 for measuring the energy distribution of secondary electrons emitted from the surface of the sample; an evacuation mechanism 160 for evacuating the vacuum vessel 110; and a control section 170 for controlling these various parts. Note that the spectra measuring device 100 is of a construction similar to a “scanning-type Auger electron microscope”.

The vacuum vessel 110 is earthed and held at a ground potential.

The sample stand 120 is provided inside the vacuum vessel 110, the voltage applying section 121 is externally provided, and the set-up is such that a prescribed negative voltage can be applied.

A cable 122 is provided from the voltage applying section 121 to the sample stand 120 such that a negative voltage can be applied to the sample.

The ion gun 140 generates positive ions from an inert gas (He, Ne, Ar, Kr, Xe, or Ra), and irradiates the sample. Here, Argon positive ions (Ar⁺) are used as the positive ions.

The electron spectrograph 150, which is provided in proximity to the surface of the sample, receives secondary electrons emitted from the surface of the sample, and measures the distribution of energy levels (the secondary electron spectrum) for the received electrons.

The evacuation mechanism 160 is capable of evacuating an internal part of the vacuum vessel to a high vacuum.

The control section 170 controls the operations of the voltage applying section 121, the electron gun 130, the ion gun 140, the electron spectrograph 150, and the evacuation mechanism 160, according to instructions inputted by an operator.

(Description of the Evaluating Device Operations)

In the spectra measuring device 100 of the above construction, an operator mounts the sample on the sample stand 120.

Following instructions from the operator, the control section 170 causes the various units to function as described below.

The control section 170 causes the evacuation mechanism 160 to evacuate the vacuum vessel 110 to a high vacuum (for example 1*10⁻⁷ Pa).

Further, the control section 170 causes the voltage applying section 121 to apply a prescribed negative voltage (−25 V to −55 V) to the sample. This has the effect of holding the surface of the sample at a negative potential with respect to the various surrounding parts, including the vacuum vessel 110, the electron gun 130, the ion gun 140 and the electron spectrograph 150.

Maintaining these conditions, the control section 170 causes either the electron gun 130 to irradiate the sample with electrons or the ion gun to irradiate the sample with inert gas positive ions, and causes the electron spectrograph 150 to operate.

As ions or electrons collide with the surface of the sample, secondary electrons are emitted therefrom. In order to accurately measure the rise position in the secondary electron spectrum at this time, a negative bias is applied to the sample.

The energy distribution of the emitted secondary electrons is measured by the electron spectrograph 150, and the measured secondary electron spectrum data is transferred to the analyzing device 200.

The analyzing device 200 receives the secondary electron spectrum data from the electron spectrograph 150, and by analyzing the data, finds information (evaluation values) for evaluating the properties of the sample.

Note here that various forms of measurement of secondary electron spectra are possible using the spectra measuring device 100, just as various forms of analysis are possible using the analyzing device 200. These are described in (1) to (3) below.

Note also that the various spectral data discussed here were obtained from measurements on samples each constituting an MgO film, 500 nm thick, formed on an Si substrate via electron beam deposition.

(1) Measuring secondary electron spectra over time during ion beam irradiation.

(Analysis of Peaks Due to Kinetically Emitted Secondary Electrons)

In the spectra measuring device 100, measurements are taken over time of the spectrum of secondary electrons (Auger electrons) kinetically emitted from a sample that is being irradiated by the ions from the ion gun 140. During this period, a negative voltage is continuously applied to the sample by the voltage applying section 121. Here, the value of the applied negative voltage corresponds to a vacuum level Evac, and the energies of the kinetically emitted secondary electrons are distributed between energy levels in proximity to the vacuum level Evac and higher energy levels.

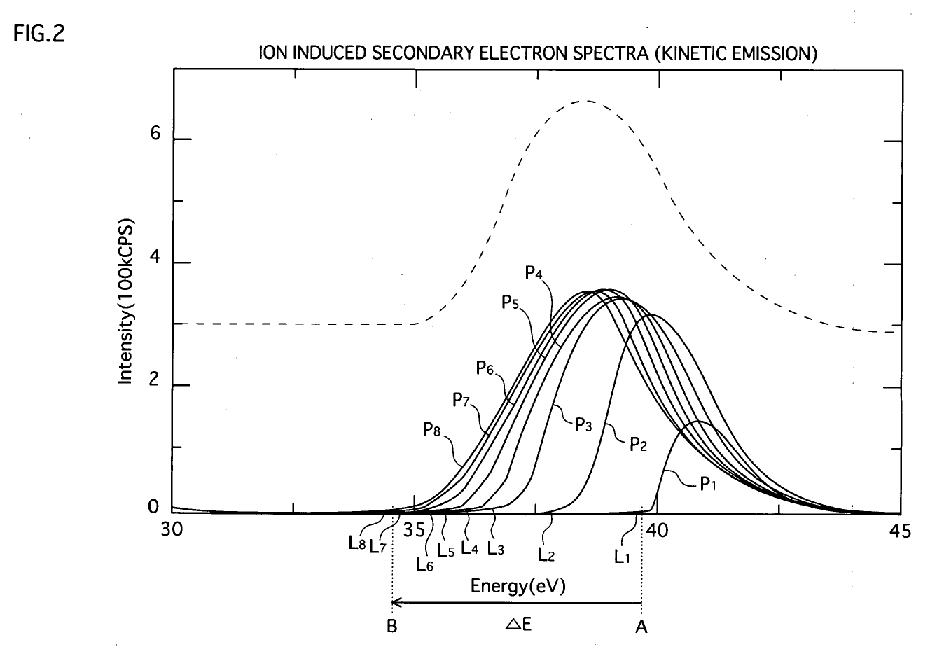

FIG. 2 shows examples of such spectra, observed when the negative bias applied by the voltage applying section 121 was −40V and the ion gun 140 was radiating 1 keV of Ar⁺ ions at a beam current of 90 nA.

As shown in FIG. 2, in secondary electron spectra, the peaks due to kinetically emitted secondary electrons (ion induced secondary electrons) appear between energy levels in proximity to the vacuum level Evac (23 eV), which corresponds to the applied negative bias voltage (−40 V), and higher energy levels. Furthermore, a peak rise position in the secondary electron spectra varies over time.

In FIG. 2, peaks P1 to P8 are peaks that appeared in secondary electron spectra measured at regular intervals (of several tens of seconds), beginning after the start of ion irradiation.

The rise positions L1 to L8 for the various peaks P1 to P8 shift in numerical order from point A to lower energies, converging on point B (i.e. the large amount of shift between the rise positions L1 and L2 progressively reduces, and is all but zero between rise positions L7 and L8).

The analyzing device 200 finds a convergence time T1, which is the time needed between starting irradiation and convergence of the rise positions (the time needed to observe P8 after observing P1), and a shift amount ΔE, which is the amount by which the position of the rise has shifted between a time immediately after the beginning of irradiation and the time of convergence (the distance between A and B in FIG. 2). T1 and ΔE are then used as evaluation values. Note that for the example measurements shown in FIG. 2 the convergence time T1 was approximately 5 minutes.

The following is an example of the type of evaluation possible using evaluation values (convergence time T1 and shift amount ΔE) obtained in this way.

The above described shift over time, and convergence of the peak rise positions is thought to occur because upon irradiation with positive ions, the surface part of the sample (the insulating film) gradually stores up charge and saturates. Hence, the shorter the convergence time T1, the shorter the time taken for charge to saturate the surface part of the insulating film.

Further, this peak rise position corresponds to the vacuum level Evac, so a larger shift amount ΔE in the rise position indicates a larger variation in surface potential at the insulating film surface as the surface is irradiated with ions, and this is a indicator that the charge barrier stored on the surface of the insulating film is large.

(2) (Analysis of the Secondary Electron Peak of the Low Energy Region During or After Ion Beam Irradiation)

In secondary electron spectra from during ion beam irradiation a peak appears due to the ion induced secondary electrons, as described above. However, a peak also appears in a lower energy level region.

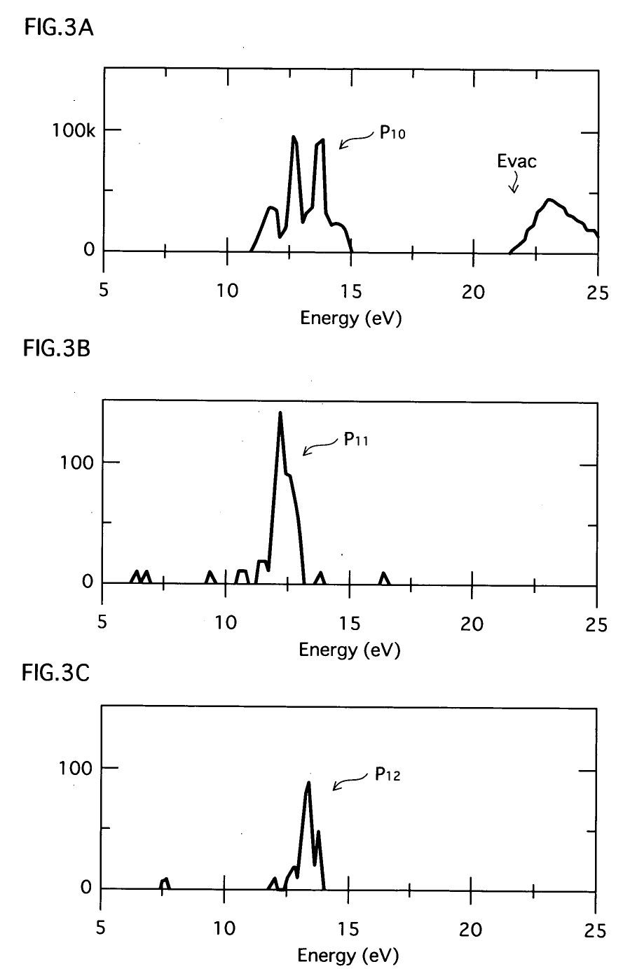

FIG. 3A is an example of a secondary electron spectrum observed during ion irradiation performed with the same irradiation conditions (the sample, the Ar⁺ ions, and the like) as in (1).

As shown in FIG. 3A a peak due to ion induced secondary electrons is seen in the region above the vacuum level Evac, which corresponds to the applied negative bias (23 eV). However, a peak is also seen in an energy level region that is approximately 10 eV lower than the ion induced secondary electron peak. Unlike the first peak, which was due to kinetic emission, this second low energy level peak is considered to be a result of electric field emission.

Further, a secondary electron spectrum is measured over time by the spectra measuring device 100 after ion irradiation, carried out according to the conditions discussed above, has stopped.

FIGS. 3B and 3C are examples of secondary electron spectra from 2 and 4 minutes after irradiation had stopped, in which a peak is seen in a lower energy level region than for kinetic emission.

As seen in FIGS. 3B and 3C, though after irradiation has stopped no secondary electron peak due to kinetic emission appears in the secondary electron spectrum, a secondary electron peak is observed in a low energy level region.

Low energy level secondary electron peaks observed in this way, either during or after irradiation, strongly relate to a capability of an insulating film to emit secondary electrons from its valence bands. Hence, it is possible for the analyzing device 200 to carry analysis over time of the low energy level peaks of the type shown in FIG. 3A to 3C, and find indicators (evaluation values) for evaluating the properties of the insulating film.

Specifically, the smaller the difference between the vacuum level Evac, which corresponds to the applied negative bias, and the energy levels of the low energy peaks (P10, P11 and P12), the easier it is for secondary electrons to be emitted from the valence bands in the insulating film. Thus, it is possible to calculate these differences in the analyzing device 200 and use them as evaluation values for the insulating film.

Further, as another example, the greater the intensity (indicated by the height of peak P10 or the average height of peaks P11 and P12, for example) of the low energy level secondary electron peaks (P10, P11, P12) either during or after ion irradiation, the easier it is for secondary electrons to be emitted from valence bands of the insulating film. Thus, it is possible to calculate these intensities in the analyzing device 200 and use them as evaluation values for the insulating film.

Alternatively, since the rate of change in intensity (variation speed) in these low energy level secondary electron peaks (P10,P11 and 12) also indicates a charging characteristic of the insulating film, it is possible to calculate the variation speed in the analyzing device 200 and use it as evaluation value for the insulating film.

The calculation of the variation speed is effected by measuring, for instance, the extent to which the intensities of peaks P11 and P12 are lower than peak P10. Another possibility is to measure the time taken after the ion irradiation has stopped for the measured peak intensity to fall to a prescribed proportion of the intensity of peak P10.

Such evaluation values are considered to be effective as indicators for showing the charge characteristics and valence band electron emission characteristics of an insulating film.

Note also that the peak shape in the low energy level secondary electron emission spectrum from during irradiation, which is shown in FIG. 3A, varies over time over the period of the irradiation. Moreover, it is considered that the rate of variation of the peak intensity in this low energy level secondary electron emission spectrum is related to the responsiveness (discharge time lag) of the insulating film. Hence, it is possible to calculate this rate of variation in the analyzing device 200, and use it as an evaluation value for the insulating film.

(Method for Time Integration of the Secondary Electron Spectra)

As described above, the electrons emitted after the ion irradiation has stopped are observed dispersed over time. Hence, it is preferable that the secondary electron spectra are integrated over time in the analyzing device before analysis is performed.

This type of combined spectrum, obtained by integration, can be said to show the energy distribution of electrons emitted after irradiation has stopped in a more quantitative manner.

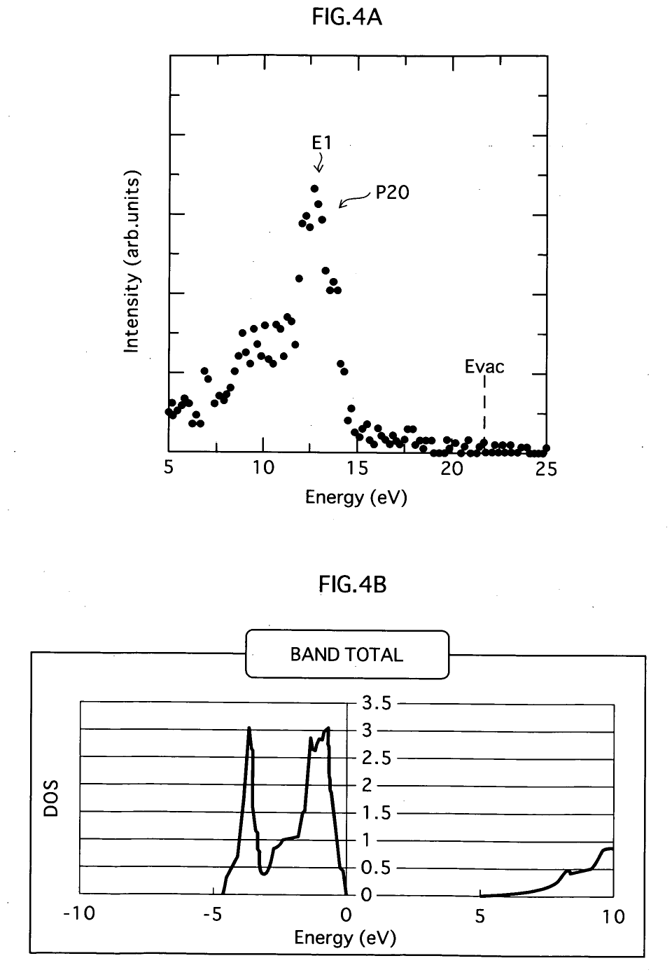

FIG. 4A is an example of a combined spectrum, obtained by integrating all the secondary electron spectra measured over time after ion irradiation, like those of FIGS. 3B and C.

If in the analyzing device 200, the difference between the vacuum level Evac and the energy level E1 where the low energy level secondary electron peak P20 occurs, or the peak intensity of the low energy level secondary electron peak P20, is obtained from a combined spectrum obtained in this way and used as an evaluation value, it is possible to accurately evaluate the characteristics of the sample insulating film.

Moreover, it is considered that the shape of the low energy level secondary electron peak P20 in this combined spectrum reflects the valence band wave form for the insulating film. Hence, by analyzing this “shape of the low energy level secondary electron peak of the combined spectrum”, the analyzing device 200 can obtain evaluation values for the insulating film.

For example, the following evaluation is possible: emission of secondary electrons from the valence bands is easier when, in the shape of the low energy level secondary electron peak P20, the intensity is higher on the high energy level side than on the low level side. To be specific, for the low energy level peak P20 shown in FIG. 4A, which is seen in the 5-15 eV range; the nearer the highest peak is to the 15 eV position and the higher the peak value, the easier it becomes for secondary electrons to be emitted from the valence band. Note also, it is possible to estimate that, the higher the peak value is, the easier it becomes to positively charge the insulating film.

((2) Knowledge on which Evaluating Method is Based)

Conventionally, when γ coefficients were measured, secondary electron spectra were not measured, and low energy level electron emission was not observed.

The present inventors, on the other hand, cleaned the surface of the insulating film sample (MgO) using ion irradiation, looked at electron emission at low energy levels during ion beam irradiation, and observed secondary electron spectra during ion irradiation. Further, they noticed that this low energy level electron emission continues even after ion irradiation has stopped (see FIG. 3A-3C).

From the results of their observations, they discovered that the energy distribution of the low energy level electrons emitted after the ion irradiation has stopped had a pulse form. Also, these electrons were not emitted continuously, but scattered over time (spike form).

This low energy level secondary electron emission is understood to be electric field emission from the positively charged surface of the insulating sample, and is considered to be a type of self-sustained emission.

Further, it was considered that these low energy level secondary electrons were emitted from the valence bands of the insulating sample, and noticed that the shape of the low energy level secondary electron peaks observed during or after ion irradiation reflected the form of the electron density of states in the valence bands of the insulating film.

An explanation of this point is given below with reference to FIG. 4. In the combined spectrum of FIG. 4A, the convergence rise position (21.8 eV) of the kinetically emitted secondary electron peak corresponds to the vacuum level Evac. The energy difference between this rise position and the fall position of the low energy level secondary electron peak is 7 eV.

FIG. 4B, on the other hand, is a valence band wave form obtained via a band calculation using an APW method for MgO identical to the MgO used in the sample film, and shows the DOS (Density of States) at each energy level.

In this figure, 0 eV on the horizontal axis corresponds to the top valence band Ev of MgO, and the energy difference between the top valence band Ev and the vacuum level Evac is 7 eV. Upon consideration of this result, it was suggested that the secondary electrons measured after ion irradiation were emitted from the valence bands of the insulating film.

Further the present inventors discovered that they could find out the state of electrons in the valence bands near the surface of the sample by looking at the form of the combined spectrum. The combined spectrum of FIG. 4A and the result of the band calculation shown in FIG. 4B resemble each other in terms of the shape of the peaks, and this too suggests that the two are strongly related.

Moreover, the inventors discovered that characteristics such as the intensity, the position, and the shape of the low energy level secondary electron peak measured for the insulating film correlated strongly with a capability of a surface region of the film to emit secondary electrons and with a capability of the surface of the insulating film to become charged with a positive charge.

Based on this information, the inventors realized that they could find the valence band electron density of states in the surface region of the sample by observing the shape of the combined spectrum. Also, since this density of states correlates with the charging capability and the emission capablity, it is possible to evaluate the electron emission properties for the region near the surface of the insulating film and evaluate properties relating to the charging of the surface (such discharge starting voltage, discharge time lag, and the like), by analyzing the measured spectrum.

With regard to an MgO protective layer of a PDP, in particular, it is possible to accurately evaluate properties relating to the MgO protective layer in an operating PDP (such as the discharge starting voltage, the time lag, and the like) by analyzing the low energy level secondary electron peak. The reason for this is considered to be that the mechanism for the emission of secondary electrons from the MgO layer in an operating PDP is the Auger process.

(3) (Analysis of Peak Rise in Secondary Electron Spectra Caused by Electron Beam Irradiation)

In the spectra measuring device 100, a spectrum for secondary electrons emitted from the sample is measured as the electron gun 130 irradiates the sample and the voltage applying section 121 applies a negative bias voltage.

Here, a number of secondary electron spectra measurements are carried out as the current of the irradiating electron beam from the electron gun 130 is varied between values.

Then, the measured spectra are analyzed in the analyzing device 200 to find evaluation values for evaluating an insulating film.

Specifically, as the current of the irradiating electron beam from the electron gun is varied, the position of the peak in the secondary electron spectra changes, and the analyzing device 200 finds a trend in the changing peak position. For example, the extent of change in the peak rise position when the electron beam current is varied by a prescribed amount, the peak rise position when the electron beam current is close to 0, or the like may be investigated and the results used as evaluation values for evaluating the insulating layer.

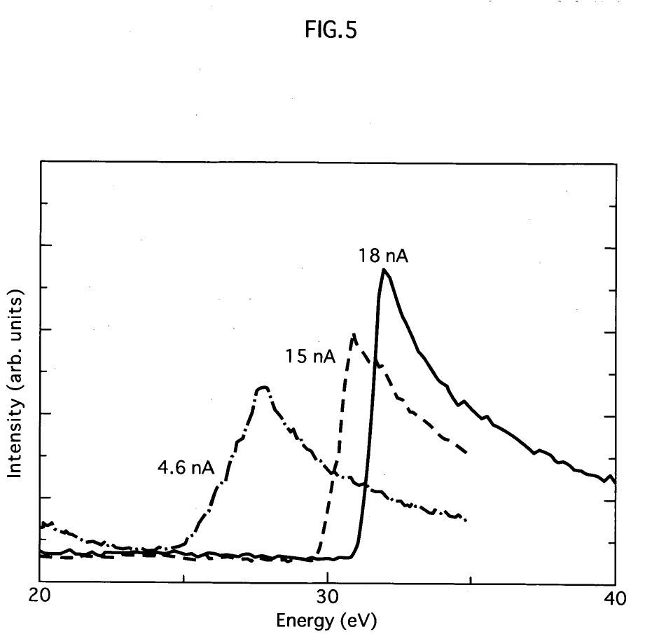

FIG. 5 shows examples of secondary electron spectra observed as the sample was irradiated with an electron beam, the observations taking place when the currents of the radiating electron beam were 4.6 nA, 15 nA, and 18 nA respectively. The sample used in these measurements was an MgO film, 500 nm thick, formed on a Si substrate via electron beam deposition, as in (1) and (2) above.

As shown in FIG. 5, in secondary electron spectra measured during electron radiation, peaks due to kinetically emitted secondary electrons are seen. Further, it can be seen that the larger the irradiating beam current, the higher the energy at which the peaks appear.

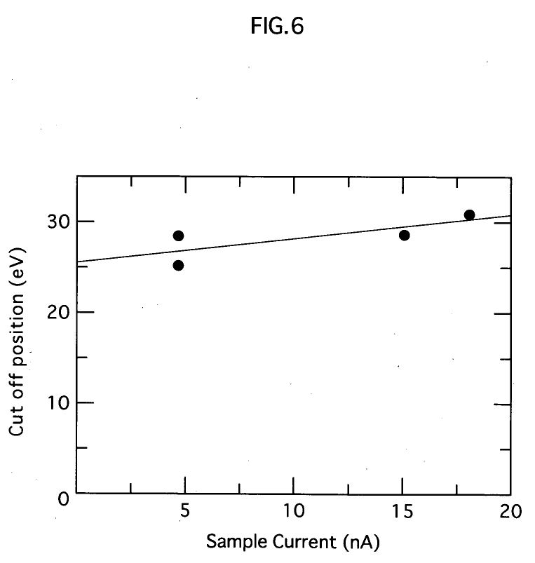

FIG. 6 is a characteristic plot with the rise positions of the various peaks shown in FIG. 5 plotted against the current of the electron beam.

As shown in FIG. 6, as the electron beam current increases, the rise position of the kinetically emitted secondary electron peak also increases with an approximately constant slope.

In the figure, the various points of the plot are joined using a straight line. This straight line shows the properties of the sample, its slope indicating the extent to which the rise position varies as the electron beam current is varied by a prescribed amount, and its intersection with the vertical axis, at a beam current of 0, indicating the peak rise position when the beam current is 0.

Here, “the slope” is related to a resistance value for the insulating layer, and can be used as an evaluation value for evaluating the insulating properties of the insulating film. For example, it is possible to evaluate whether or not the insulating properties are favorable (the insulating layer has few defects) from the slope (the larger the slope, the more favorable the insulating properties). Since for the protective MgO layer in a PDP, the insulating properties of the protective layer relate to the discharge starting voltage and the discharge time lag in a PDP, it is considered possible to evaluate the discharge starting voltage and the discharge time lag based on the “slope” measured for the MgO protective layer.

Further, the “peak rise position at an electron beam current of 0” correlates with surface potential of the insulating layer, and can therefore be used as an evaluation value for evaluating the extent to which the insulating film will accumulate charge.

### Second Embodiment

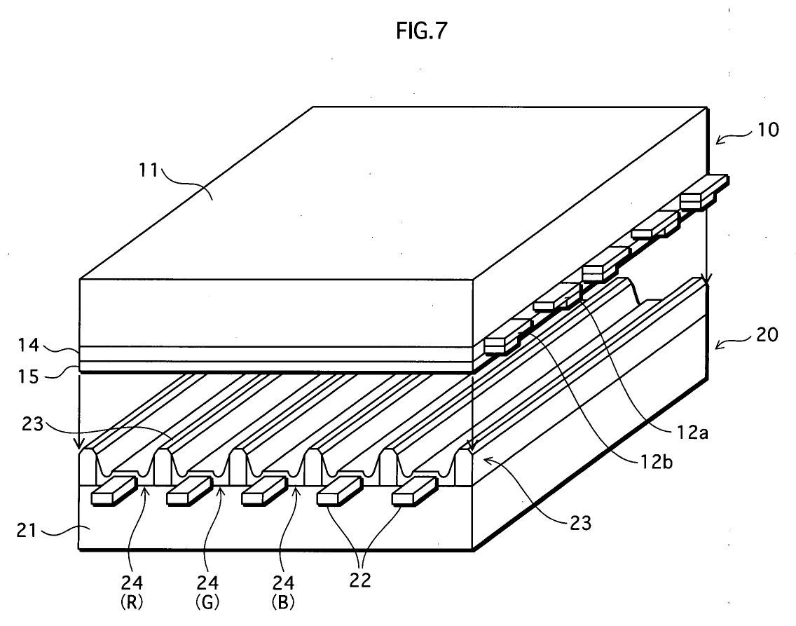

FIG. 7 is a perspective view showing the structure of the present embodiment of an AC surface discharge type PDP. As shown in the figure, the PDP is constructed with a front panel 10 and a back panel 20. The front panel includes display electrodes 12a and 12b, a dielectric layer 14, and a protective layer 15, on a front glass substrate 11. The back panel 20 includes data electrodes 22, barrier ribs 23 disposed in a stripe pattern, and phosphor layers 24 composed of red, green and blue ultra-violet light excited phosphors disposed between the barrier ribs 23, on a back glass substrate 21. The front panel 10 and the back panel 20 are joined so as to oppose one another and leave the space between them, and a discharge gas is enclosed in a space between the panels. Discharge cells are formed in the display area at points where the display electrodes and data electrodes cross over.

Further, when the PDP is manufactured, the display electrodes 12a and 12b, the dielectric layer 14, and the protective layer 15 are formed on the front glass substrate 11 in the stated order to make the front panel 10; components such as data electrodes 22, barrier ribs 23, phosphor layers 24 are formed in the back glass substrate 21 in the stated order to make the back panel 20; and the front panel 10 and the back panel 20 are combined by way of a bonding process using a bonding agent.

In the present embodiment, a test area for evaluating the properties of the protective layer is provided on the front panel 10, a protective layer being formed in the test area as well as in the display area. Before combination with the back panel 20, spectra of secondary electrons emitted from the surface of the protective layer are measured in the way described in the First Embodiment by performing ion beam irradiation, or electron beam radiation, on the test area of the front panel 10, and evaluation of the protective layer is carried out using the resulting measurements.

If, before combination with the back panel 20, evaluation of the protective layer on the front panel 10 is carried out in this way, it is possible to manage the manufacturing process precisely by using the results from the evaluation as feedback to adjust the manufacturing conditions in the process for forming the protective layer.

Further, since it is possible to choose and combine with the back panels 20 only front panels 10 whose protective layers 15 have satisfactory characteristics, and to not use front panels whose protective layers 15 have unsatisfactory characteristics, the yield subsequent to the combination process can be improved.

Moreover, since the results from the evaluation are considered to reflect the suitability of the protective layer manufacturing conditions, if for example, evaluation of the protective layer is performed after the protective layer has been formed using electron beam deposition, it is possible to feed back the results of the evaluation into the protective layer forming process, and control conditions (such as the electron beam deposition conditions) of this process so as to make them appropriate.

A more detailed description of the method for carrying out the evaluation of the protective layer 15 using a test area provided on the front panel 10 is included below.

(Construction of Front Panel Test Area)

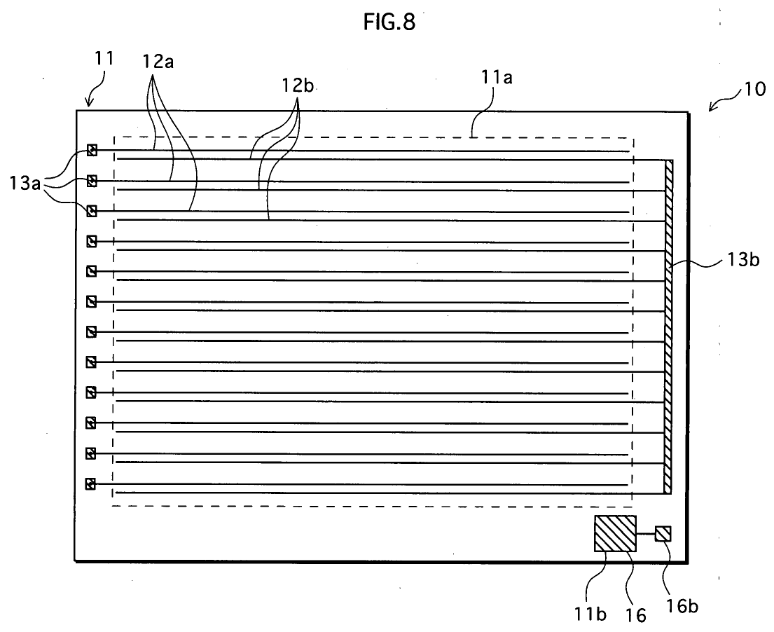

FIG. 8 is a plan view of the front panel 10 used in an AC surface discharge type PDP.

As shown in FIG. 8, on the front panel 10, a display area 11a for carrying out image display is provided on the glass substrate 11, and a test area is provided outside the display area 11a.

In FIG. 8 the test area is provided in proximity to the corner of the front glass substrate 11. However, as long as the test area is not positioned over lines to the display electrodes 12a and 12b or the electrode pads 13a and 13b, it may be positioned anywhere outside the display area. On the front glass substrate outside the display area there are generally spaces where electrodes are not disposed, and one of these can be used as the test area.

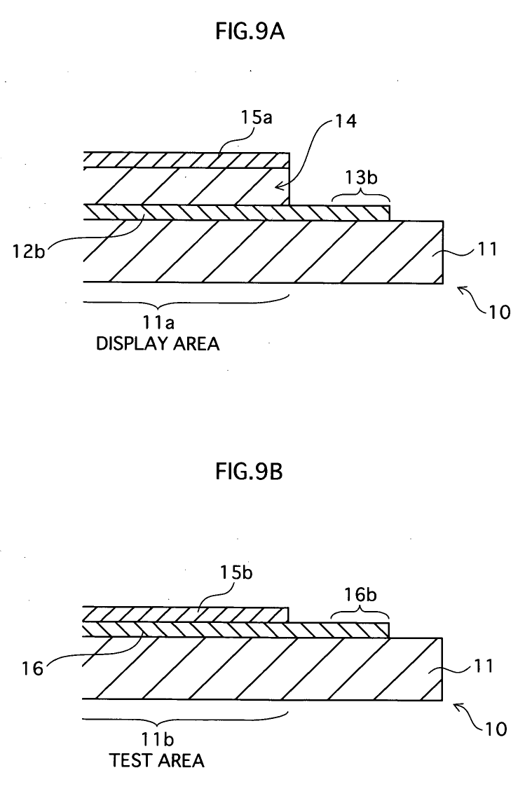

FIGS. 9A and 9B are cross-sectional views of part of the front panel 10, 9A being a cross-section along display electrode 12b in the display area 11a, and 9B being a cross-section through the test area.

As shown in FIG. 8, the display electrodes 12a and 12b are provided over the whole of the display area 11a in a stripe pattern. The ends of the display electrodes 12a and 12b extend outside the display area 11a, and connect to the electron pads 13a and 13b, which are for receiving a driving voltage from an external supply.

Further, a dielectric layer 14 composed of a dielectric glass material is formed across the whole of the display area 11a so as to cover the display electrodes 12a and 12b, and a protective layer 15a composed of magnesium oxide (MgO) is formed on the surface of the dielectric layer 14. In FIG. 9A the display electrode 12b, the dielectric layer 14, and the protective layer 15a are shown layered in the stated order on the front glass substrate 11 in the display area 11a.

On the other hand, as shown in FIG. 8, in the test area 11b, a measurement-use electrode 16 is provided covering the whole test area, and a test-use protective layer 15b composed of MgO forms a layer on the measurement-use electrode 16. Further, the measurement-use electrode 16 is connected to a measurement-use electrode pad 16b.

(Test Area 11b Details)

The measurement-use protective layer 15b is for measuring the behavior of the protective layer 15a in the display area 11a. Therefore, when manufacturing the front panel 10, it is necessary that the protective layer 15a and the test-use layer 15b be formed using the same method, and it is preferable if both layers are formed simultaneously using a method such as vapor deposition.

Normally, display electrodes 12a and 12b, and electrode pads 13a and 13b are formed using silver or a conducting material such as ITO, and it is preferable if the measurement-use electrode 16 and the measurement-use electron pad 16b are formed using identical silver or ITO. Note that the display electrodes 12a and 12b, the measurement electrode 16, and the various electrode pads 13a, 13b, and 16b can be formed simultaneously.

Since there is a measurement-use electrode lying under the test-use protective layer 15b in this way, it is possible to stably apply a negative voltage to the test-use protective layer 15b via the measurement-use electrode 16.

Note that, as shown in FIG. 9B, having the test-use protective layer 15b disposed directly onto the measurement-use electrode 16 without an intermediary dielectric layer is desirable because a negative voltage can be stably applied to the whole test-use protective layer.

It is desirable that the test area 11b is wide enough to entirely accommodate the electron beam spot from the electron beam gun 130 or the ion beam spot from the ion beam gun 140. Considering that the ion beam spot, being comparatively difficult to make convergent, is likely to widen, it is preferable that the test area is at least a few mm² to ensure that the entire beam spot can be accommodated.

(Method for Measuring Secondary Electron Spectra Using the Test Area of the Front Panel 10)

Measurement of these spectra is performed using the spectra measuring device shown in FIG. 1, and is carried out as follows.

The front panel 10 is mounted on the sample stand 120.

Here, the front panel is set up such that the test area 11b is irradiated by the electron beam from the electron gun 130 and the ion beam from the ion gun 140. Further, the cable 122 connects to the measurement-use electrode pad 16b such that the voltage applying section 121 can apply a negative voltage to the measurement-use electrode 16.

As described in the First Embodiment, the inside of 110 is evacuated, the test area 11b is irradiated with an ion beam or an electron beam while a negative voltage is applied to the measurement-use electrode 16 using the voltage applying section 121, and the spectra of secondary electrons emitted from the test-use protective layer 15b are measured. Then, evaluation of the test-use protective layer 15b is carried out by analyzing the measured spectra in the analyzing device 200. This evaluation of the test-use protective layer 15b can be used unchanged as an evaluation of the display area protective layer 15a.

Specifically, with regard to the test-use protective layer 15b, the analyzing device 200 finds the evaluation values described in the First Embodiment, (including “convergence time T1”, “shift amount ΔE”, “the difference between the vacuum level Evac and the energy level of the low energy level peak”, “the intensity of the low energy level secondary electron peak”, “the variation in the position of the peak rise position with the variation of the peak rise position”, and “the peak rise position at an electron beam current of 0”. By judging whether or not these evaluation values fall within a set of standard ranges measured with regard to standard samples known in advance to have favorable properties, it is possible to decide whether or not the protective layer 15a in the display area has suitable discharge and charge characteristics.

Note that though, in FIG. 7 only one test area 11b is provided for the evaluation of the whole of the protective layer 15a, it is possible to partition the display area 11a into a number of smaller areas, provide each area with a corresponding test area 11b, and evaluate the protective layers separately, area-by-area. This makes it possible to evaluate variation between the protective layers in the various areas, and hence, to make a more informed decision about the quality of the front panel.

(Effect of the Measuring Methods Described in the First and Second Embodiments)

Normally, it is extremely difficult to obtain information relating to the occupation state of the valance bands in the region near the surface of an insulating material. However, it is possible to find this information relatively easily by measuring and analyzing spectra over time, or by obtaining and analyzing combined spectra, as described above.

Thus, the measuring method of the above-described present invention is useful for evaluating, for instance, the valence band electron emission properties and the charge properties of an insulating layer.

Further, the above-described measuring method is considered to be particularly useful for evaluating an MgO layer used as a protective layer in a PDP.

Thus, whereas conventionally, in an ordinary γ coefficient measuring method, the sample was irradiated with ions and the total quantity of emitted secondary electrons measured, in the present invention, secondary electron spectra are measured in the way described above. This makes it possible to obtain more accurate information relating to the form of the valence bands of the protective layer. Since the form of the valence bands affects the discharge characteristics of an operating PDP, obtaining this information makes it possible to simply asses whether or not the discharge characteristics (such as the firing voltage and the discharge time lag) of the assembled PDP will fall within prescribed ranges.

Thus, applying this method in the PDP manufacturing process, after the manufacture of a front panel, if evaluation values for the protective layer on the front panel are obtained using the evaluating device, if a quality decision is made based on these evaluation values, and if front panels whose quality judgment results are favorable are laminated together to back panels, it is possible to keep the discharge characteristics (such as the discharged voltage and the discharge time lag) for the assembled PDP within suitable ranges.

For instance, the higher the peak intensity of the low energy level secondary electron peak P20 measured for an MgO protective layer, the lower the firing voltage tends to be in the assembled panel. Hence, if the manufacturing process is controlled such that the peak intensity never falls below a threshold value, the starting firing voltage of the manufactured PDP can be kept within a low range.

Hence, by providing processes for evaluating the protective layer of the front panel, the yield of the PDP manufacturing process can be improved.

(Modifications to the First and Second Embodiments)

Although the above description centered on the measurement and evaluation of the protective layer in a PDP, the method is also applicable to a dielectric glass layer in a PDP. If the dielectric glass layer is irradiated with ions or electrons using the same method and its spectra measured, its surface state can be analyzed and its properties evaluated based on the measured spectra.

Further, the same method is widely applicable to films that have a comparatively low discharge starting voltage with respect to the discharge gas used in PDPs, or to films that have a comparatively large Auger process secondary electron emission coefficients, including insulating films composed of SrO2, La2O3, and AlN. If any such film is irradiated with ions or electrons and the resulting spectra are measured, its surface state can be analyzed and its properties evaluated based on the measured spectra.

Further, the evaluating method of the present invention can be widely applied, not only to evaluate properties relating to PDPs, but also to evaluate the charge and electron emission properties of insulating and semi-conducting films for components such as gas discharge panels and the like, which include insulating or semi-conducting films that emit electrons from their surface.

Moreover, the evaluating method of the present invention is not limited to discharge display components, but can be widely applied to any component having an insulating film or semi-conductor film in order to evaluate the electron emission properties and the charge properties, or the electron states, of the film.

For example, it is possible to evaluate the transistor characteristics of any component containing transistors by evaluating the insulating and semi-conducting films in the component using the evaluating method of the present invention.

As for film type, the wide application of the methods of the present invention not only to films of inorganic materials, but also to insulating and semi-conducting films composed of organic materials can be anticipated.

In the above description, the spectra measured by the spectra measuring device 100 are received and analyzed by the analyzing device 200, but the spectra measured by the spectra measuring device 100 may equally be displayed on a display device and analyzed by a user.

### INDUSTRIAL APPLICABILITY

As described above, the measuring device, the measuring method, and the evaluating device of the present invention can be applied in the manufacture of gas discharge panels such as PDPs, discharge display components and components containing transistors, contributing to an improvement in the yields of the manufacturing processes for these components.

1. An insulating film measuring device for evaluating properties of an insulating film, the insulating film measuring device comprising:
an ion irradiating unit operable to irradiate the insulating film with ions; and
a spectrum measurement unit operable to measure a spectrum of secondary electrons emitted from the insulating film during ion irradiation.

2. The insulating film measuring device of claim 1,
wherein the spectrum measurement unit measures, over time, the spectrum of secondary electrons emitted from the insulating film.

3. An insulating film evaluating device comprising:
the insulating film measuring device of claim 2; and
a variation detection unit operable to detect, based on a secondary electron spectrum measurement result measured over time by the spectrum measurement unit, at least one of an amount of variation of a rise position of a peak due to kinetic emission of secondary electrons and a rate of variation of the rise position.

4. An insulating film evaluating device comprising:
the insulating film measuring device of claim 2; and
a variation detection unit operable to detect, based on a secondary electron spectrum measurement result measured over time by the spectrum measurement unit, variation in a peak appearing at a lower energy level than the peak due to kinetic emission of secondary electrons.

5. An insulating film measuring device for evaluating properties of an insulating film, the insulating film measuring device comprising:
an ion irradiation unit operable to irradiate the insulating film with ions; and
a spectrum measurement unit operable to measure a spectrum of secondary electrons emitted from the insulating film after ion irradiation has stopped.

6. The insulating film measuring device of claim 5,
wherein the spectrum measuring device measures, over time, the spectrum of secondary electrons emitted from the insulating film.

7. An insulating film evaluating device comprising:
the insulating film measuring device of claim 5; and
an intensity detection unit operable to detect, based on a spectrum measured by the spectrum measurement unit, an intensity of a peak appearing at a lower energy level than a peak due to kinetic emission of secondary electrons.

8. An insulation film evaluating device comprising:
the insulating film measuring device of claim 6; and
a variation detection unit operable to detect variation in a peak appearing at a lower energy level than the peak due to kinetic emission of secondary electrons.

9. An insulating film measuring device for evaluating insulating film properties, the insulating film measuring device comprising:
an ion irradiation unit operable to irradiate the insulating film with ions; and
a spectrum measurement unit operable to a measure a spectrum of secondary electrons emitted from the insulating film during ion irradiation and after the ion irradiation has stopped.

10. An insulation film evaluating device comprising:
the insulating film measuring device of claim 9; and
a determining unit operable to determine, after ion irradiation has stopped, based on the spectrum measured by the spectrum measurement unit, an energy difference between a first peak due to kinetic emission of secondary electrons measured during ion irradiation and a second peak appearing at a lower energy level than the first peak.

11. An insulating film measuring device for evaluating insulating film properties, the insulating film measuring device comprising:
an electron irradiation unit operable to irradiate the insulating film with an electron beam of variable intensity; and
a spectrum measurement unit operable to measure a spectrum of secondary electrons emitted from the insulating film during electron irradiation.

12. An insulating film evaluating device comprising:
the insulating film measuring device of claim 11; and
a variation measurement unit operable to detect, as the electron beam intensity varies, variation in a rise position of a peak that appears in a secondary electron spectrum measured by the spectrum measurement unit.

13. An insulating film measuring method used for evaluating properties of an insulating film, the insulating film measuring method comprising:
an ion irradiation step of irradiating the insulating film with ions; and
a spectrum measurement step of measuring, at least one of during and after the ion irradiation, a spectrum of secondary electrons emitted from the insulating film.

14. An insulating film evaluating method including a density of states measurement step of measuring, based on the spectrum measured in the insulating film measuring method of claim 13, the electron density of states in valence bands of the insulating film.

15. An insulating film measuring method for evaluating properties of an insulating film, the insulating film measuring method comprising:
an electron irradiation step of irradiating the insulating film with electrons while varying an electron beam intensity; and
a spectrum measurement step of measuring a spectrum of secondary electrons emitted from the insulating layer during electron beam irradiation.

16. An insulating film evaluating method including a density of states measurement step of measuring, based on the spectrum measured in the insulating film measuring method of claim 15, the electron density of states in valence bands of the insulating film.

17. A discharge display component substrate having a display area, the display area including display electrodes for applying a voltage during discharge display and a display-use insulating film covering the display-use electrodes,
wherein, on the substrate,
a test area for measuring the properties of the insulating layer is provided, and
in the test area, a test-use insulating film identical in type to the display-use insulating film is provided.

18. The discharge display component substrate of claim 17,
wherein the test-use insulating film is sufficiently spacious to accommodate irradiation from a whole ion beam from an ion beam irradiation device.

19. The discharge display component substrate of claim 17,
wherein the test area is provided outside the display area.

20. The discharge display component substrate of claim 17,
wherein a test-use electrode for applying a voltage from an external source is sandwiched between the test-use insulating film and the substrate.

21. The discharge display component substrate of claim 20,
wherein the display electrodes and the test-use electrode are formed from a same type of material.

22. The discharge display component substrate of claim 20,
wherein an electrode pad to which the voltage is applied and the test-use electrode are connected.

23. The discharge display component substrate of claim 17,
wherein the display-use insulating film and the test-use insulating film are formed simultaneously.

24. A plasma display panel comprising:
the discharge display component substrate of claim 17; and
a second substrate disposed disposed an interval away from the discharge display component substrate, so as to be opposite the display-use insulating film,
wherein a gap between the two substrates is filled with a discharge gas.

25. An insulating film evaluating method for evaluating the discharge display component substrate of claim 20, the insulating film evaluating method comprising:
an ion irradiation step of irradiating the test-use insulating film with ions while applying a negative voltage to the test-use electrode;
a spectrum measurement step of measuring, at least one of during and after ion irradiation, a spectrum of secondary electrons emitted from the test-use insulating film; and
an evaluation step of evaluating, from the measured spectrum, properties of the display-use insulating film.
